(19) United States
(12) Patent Application Publication
(10) Pub. No.: US 2004/0259382 A1
(43) Pub. Date: Dec. 23, 2004

(54) Apparatus and method of producing dope

(75) Inventors: Takuro Nishimura, Kanagawa (JP); Tadahiro Tsujimoto, Kanagawa (JP); Yukihiro Katai, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/872,568

(22) Filed: Jun. 22, 2004

(30) Foreign Application Priority Data
Jun. 23, 2003 (JP) 2003-178289

(51) Int. Cl. H01L 21/00

(52) U.S. Cl. 438/780

(57) ABSTRACT

An apparatus for producing a dope includes an extrusion machine. A cooling medium flows in a jacket in periphery of a cylinder so as to perform the cooling at −45° C. (upstream side) and −70° C. (downstream side). A screw has first-third portions. The diameter is smaller in the first portion than the third portion, and becomes larger in the second portion toward the third portion. A mixture of TAC and methyl acetate is supplied into a cylinder, whose rotation feeds the mixture from the first to the second portion. Since the space between the second portion and the cylinder becomes narrower in the downstream side, the mixture is compressed and cooled at the same time, to easily dissolve the polymer to the solvent. The dope is obtained and made uniform by the third portion. Thereafter, the dope is fed to the cooler for progress of the dissolution.

### BACKGROUND OF THE INVENTION

1. Field of the Invention

The present invention relates to an apparatus and a method of producing a dope.

2. Description Related to the Prior Art

Polymers are used in several fields, and many products are produced in several methods depending on use thereof. For example, an plastic film and the like are produced in a melt extrusion method in which polymer is heated and melt, or in a solution casting method in which the polymer is dissolved to or dispersed in a solvent to prepare a solution (hereinafter dope). In the solution casting method, the dope is cast on a substrate to evaporate the solvent, and thus the film is produced. The solvent to be used is selected so as to be adequate in consideration of several points, such as solubility of the polymer, volatility, influences on human bodies and circumstances, and the like. Especially, in recent years, the security to the human bodies and the circumstances are strongly required. Therefore, the selection of the solvent for preparing the dope becomes harder depending on sorts of the polymer.

For example, as described in Japan Institute of Invention and Innovation (JIII) JOURNAL 2001-1745, when cellulose acetate film which is often used as a photographic film base is produced from cellulose acetate (hereinafter TAC including cellulose triacetate), chlorinated methylenes (methylene chloride, dichloromethane) are used as the main solvent in the solution casting method. However, the use of the methylene chloride tends to be restricted so much, since it has influences on the human bodies and the circumstances. Accordingly, there is a method in which acetone is used since the problems of the human bodies and the circumstances are smaller in using acetone than other solvent materials. However, in this case, the TAC is hardly dissolved.

Accordingly, as shown in “J. M. G. Cowie et.al.: Makromol, Chem. 1971, Vol. 143, Page 105”, the method of producing the dope necessary for the solution casting method is applied to a cooler which is used in a extrusion machine. In this method, cellulse acetate (TAC) whose degree of substitution is from 2.80 (acetylation degree 60.1%) to 2.90 (acetylation degree 61.3%) is cooled in acetone to the temperature from −80° C. to −70° C. Thereafter the TAC in acetone is heated. Thus a solution in which TAC is dissolved such that the percentage thereof may be 0.5 wt. % to 5 wt. %. In followings, the method of preparing the dope by cooling the solvent containing the polymer is called “Cool-dissolving method”. Further, the cool dissolving method is also applied to a techniques of fiber spinning method. In this method, the conditions of the cool-dissolving method is adjusted in consideration of mechanical properties of the obtained fiber, staining properties and a sectional shape of the fiber, and the like, so as to obtain the dope whose concentration is 10 wt. % to 25 wt. %. This method is described, for example, in the essay “Dry spinning from a cellulose triacetate solution in acetone” of Kenji Kamide, in Magazine of THE TEXTILE MACHINERY SOCIETY OF JAPAN, Vol. 34, Page 57-61 (1981).

However, since the screw is usually used as a heat source in a method of producing a film in melt extrusion method, the rotation of the screw causes the heat generation. Accordingly, when the screw cooled in an extrusion machine is rotated to feed the solvent, the polymers and the like, it becomes more harder to control the cooling condition adequately. The lower cooling temperature is preferable. However, when the cooling temperature becomes lower, the viscosity becomes higher. Therefore the resistance to the screw becomes larger and the heat is easily generated. Accordingly, it becomes hard to make the feeding with keeping the cooling temperature. Further, when the rotation speed of the screw is made larger to increase the productivity, heat is generated, and the solubility becomes smaller. In order to prevent it, it is necessary to decrease the feeding speed. However, in this case, the productivity becomes lower, and the energy for cooling becomes larger, which causes the demerits in the cost for energy. Furthermore, when the concentration of the polymer is made higher, the feeding speed becomes lower too much, and there is a case that the feeding cannot be made when the concentration is at least predetermined value. Accordingly, it is required that the solubility is increased so as to improve the productivity.

### SUMMARY OF THE INVENTION

An object of the present invention is to provide an apparatus and a method of producing a dope, in which a productivity of the dope becomes larger.

Another object of the present invention is to provide an apparatus of producing a dope, in which an amount of energy to be used is decreased.

In order to achieve the object and the other object, in an apparatus for producing a dope of the present invention, an extrusion machine including a screw is a compression type. Thus the effect of mixing is increased. Further, the rotation number can be lower, and therefore the heat generation is reduced. Accordingly, the effect of cooling becomes larger.

When the dope is produced in a cool-dissolving method, the solubility depends on both of the temperature and the cooling period. When the cooling is made only in the extrusion machine, the solubility often does not become enough. In this case, a cooler is disposed in downstream from the extrusion machine, so as to keep the dope cooled also after the extrusion machine. Thus the solubility of the polymer increases. In the manner, the solubility at which the polymer dissolves to the solvent increases, and the productivity of the dope becomes larger in the cool-dissolving method. Further, in accordance with the increase of the productivity of the dope, the productivity of the film increases. Furthermore, also in the increase of the productivity of the dope, the physical properties thereof is good, and therefore the optical properties of the several products for optical use from the film produced from the dope don't become worse. Accordingly, the productivity of the products of optical used increases.

Preferably, the screw is a single shaft type. The screw is particularly preferably a double shaft type. In this case, the mixing of the dope is made more to increase the solubility. Further, when the screw is a double shaft type, the mixing is more effectively made, and at the exit, the temperature difference between the area closed to the wall and the central area becomes smaller. Thus the solubility is improved. Note that the temperature difference is preferably at most 5° C., and particularly at most 1° C. Further the screw becomes three or more shaft type, the structure of the extrusion machine becomes complicated, and the production cost becomes higher.

Note that in the present invention the structure or the sorts of the double shaft type is not restricted especially. For example, as the double shaft type, there may be a non-mesh type in which two screws are not meshed and a mesh type (including for example a partial mesh type in which two screws are partially meshed, and a entire mesh type in which two screws are entirely meshed). Further, the rotational direction of the screws may be the same or different.

The preferable embodiment of the apparatus for producing the dope includes in a cylinder a screw constructed of a screw shaft and a spiral flight. In the cylinder, raw materials are cooled. The screw includes a first screw shaft portion which has a first diameter and is positioned in a side for supply of the dope into the cylinder, a second screw shaft portion which has a second diameter larger than the first diameter and is positioned in a side for extrusion of the dope from the cylinder, and a third screw shaft portion connecting the first and second screw shaft portions. A space between the third screw shaft portion and the cylinder becomes narrower in a feeding direction of the dope. Accordingly, as the raw materials of the dope are compressed, the solute such as the polymer easily dissolves to the solvent to increase the solubility of the dope.

In the preferable embodiment of the preset invention, the raw materials or the dope is compressed at a compression rate more than 1.0 and at most 5 to the atmospheric pressure. Accordingly, the productivity of the dope increases.

In the preferable embodiment of the present invention, an apparatus of producing a dope includes an extrusion machine for producing the dope by cooling raw materials of the dope with rotation of a screw, and a cooler provided in downstream from the extrusion machine. Accordingly, a cooling area for reducing the heat generation caused by the rotation of the screw becomes the smallest. Thus the productivity of the dope is kept and the decrease of the consumed energy can be made.

In the preferable embodiment of the present invention, a cooler is provided in the downstream side of the extrusion machine. Particularly, the cooler may be another extrusion machine. In this case, the solute easily dissolves into the solvent to increase the productivity of the dope.

Further, particularly, the cooler may be a pipe of double pipe type. A cooling medium flows in an outer pipe thereof, so as to cool the cooler to the adequate temperature. Thus the solubility of the prepared dope can be kept, and the dissolution can be made furthermore. Further, as the cooler is also the pipe of double pipe type, the cost for production can be lower.

A first volume V1 of the raw materials or the dope in said first extrusion machine and a second volume V2 of the dope in a cooler 12 preferably satisfy the condition of 0.5≦(V2/V1)≦100. In this case, when the dope prepared in the extrusion machine is cooled in the cooler to make the cooling period longer. Thus the solubility in the cooler increases, and the effect of the present invention becomes larger.

An inner diameter D(mm) of said cylinder of the first extrusion machine and a inner diameter D2(mm) of an inner pipe of the double pipe satisfy the condition of 0.8<(D2/D)<10. When the pressure difference between the extrusion machine and the cooler becomes large, the dope does not smoothly flow. However, when the above condition is satisfied, the pressure difference becomes small and the dope smoothly flows.

A heater may be provided in the downstream from the cller. Thus the extrusion machine, the cooler, and the heater are arranged in this order, and when the raw materials or the dope is fed through then, the solubility increases at the most.

The present invention includes a method of producing the dope, to which the apparatus for producing the dope is applied.

In a method of producing the dope of the present invention, an extrusion machine including a screw having a shape for compressing the raw materials or the dope is used. Preferably, Thus the polymer easily dissolves to the solvent. The screw used in the extrusion machine is single shaft type.

In the preferable embodiment, as the raw materials or the dope is cooled at a cooling speed in the range of 5° C./min to 200° C./min in said extrusion machine, the temperature of the solute such as the polymer and the like and the solvent becomes to the value at which the solute dissolves so fast. Thus the productivity of the dope is increased.

As the dope prepared in said extrusion machine is cooled in 60 minutes, the polymer and the like dissolves to the solvent in the cooling, and the dope of high concentration can be produced.

The cooling of the dope is performed with use of a pipe of a double pipe type provided in a downstream from the extrusion machine. A cooling medium flowing through the outer path of the pipe of double pipe type is at least one of methanol, hydrofluoro ethers, and brine. The cooling medium is circulated with use of a circulator. Accordingly, the amount of the used cooling medium becomes smaller, and the cost becomes lower. Further, the discharge of the cooling medium into the circumstance is reduced, which has large merits in the circumstance protection.

A jacket is provided in a periphery of said cylinder of the extrusion machine, and is partitioned into two sections.

A temperature T1(° C.) at an entrance for supply of the dope into the cylinder 33 and a temperature T2(° C.) at an exit for discharge of the dope satisfy a condition, T2<T1, in the cooling. Accordingly, the raw materials are easily fed in the extrusion machine, and the temperature of the solute such as the polymer and the like and the solvent becomes to the value at which the solute dissolves so fast.

A temperature T(° C.) in the cooler and the temperature T2(° C.) of said exit of said cylinder satisfy a condition, T≦0.95×T2. Accordingly, a precipitation of the solute in the dope prepared in the extrusion machine is reduced, and the dope is further cooled with the cooler so as to dissolve the polymer to the solvent. Thus the dope of high concentration is produced.

The dope is heated at a heating speed of at least 20° C./min after being cooled. Thus the solute such as the polymer and the like are more easily dissolved to the solvent, and the dope of the high concentration can be produced.

The preferable polymer is cellulose acylate. In this case, the dope produced in the method in the present invention is preferably used in a solution casting method, so as to produce a film. Further, although the dissolution of cellulose acylate to methyl acetate is not high, the methyl acetate can be used as a main solvent for easily producing the dope. The film produced from the dope of high solubility is excellent in optical property, and used as a protective film, for a polarizing filter, which is used in a liquid crystal display. Further, the film may be used as an optical compensation sheet, which is used in the liquid crystal display. Further the film may be used as a photosensitive material.

### BRIEF DESCRIPTION OF THE DRAWINGS

The above objects and advantages of the present invention will become easily understood by one of ordinary skill in the art when the following detailed description would be read in connection with the accompanying drawings:

FIG. 1 is a schematic diagram of an apparatus for producing a dope of the present invention;

FIG. 2 is a sectional view of an extrusion machine in the apparatus of FIG. 1;

FIG. 3 is a schematic diagram of inside of the extrusion machine in FIG. 1;

FIG. 4 is a schematic diagram of another embodiment of the extrusion machine in FIG. 1;

FIG. 5 is a schematic diagram of an equipment for producing a film in a solution casting method;

FIG. 6 is a sectional view of another embodiment of the equipment for producing the film in a solution casting method;

FIG. 7 is a schematic diagram of another embodiment of the equipment for producing the film in the solution casting method;

FIG. 8 is a sectional view of another embodiment of the equipment for producing the film in the solution casting method.

### PREFERRED EMBODIMENTS OF THE INVENTION

[Solvent]

In the present invention, known solvent materials are used as a solvent. Especially preferably is used the solvent in which the polymer swells at a temperature in the range of 0° C. to 55° C. This range of the temperature is that in which a polymer solution is produced. Further, in the method of producing the dope of the present invention, the solvent material is selected such that the polymer may be swollen therein. Thus the period for producing the dope may be shorter by stirring at room or high temperature as in the prior art. Note that the solvent of the polymer may be a mixture solvent.

As the solvent, organic solvent is preferable to inorganic solvent. As the organic solvents, there are esters (for example, methyl formate, methyl acetate, ethyl acetate, amyl acetate, butyl acetate and the like), ethers (for example, dioxane, dioxolane, tetrahydrofuran, diethyl ether, methyl-t-butyl ether and the like), aromatic hydrocarbons (for example, benzene, toluene, xylene, and the like), aliphatic hydrocarbons (for example, hexane, heptane and the like), alcohols (for example, methanol, ethanol, n-butanol and the like),ketones (for example, cyclopentanone, acetone, methylethylketone, cyclohexanone and the like). Further, the mixture solvent thereof may be used.

In the present invention, it is preferable to select the solvent adequate for the polymers described below. For example, when the polymer is cellulose triacetate (TAC), polycarbonates and the polystyrenes, it is preferable to use as the solvent acetone or methylacetate. In this case, acetone or methyl acetate may be used as a single solvent (100%) or a mixture solvent containing other solvent materials. Further, when the mixture solvent is used, the acetone or the methyl acetate is preferably a main solvent (at least 50 wt. %). Further, when norbornene polymers are used as the polymer, the preferable solvents to be used are aromatic hydrocarbons (benzene, toluene, xylene, and the like), aliphatic hydro carbons (hexane and the like), ketones (acetone, methylethylketone, and the like). Also in these cases, the mixture solvent in which at least two sorts of the solvents are mixed. Further, in polymethylene methacrylate (PMMA), it is preferable to use ketones (acetone, methylethylketone and the like), esters (methyl acetate, butyl acetate and the like), and alcohols (methanol and the like). Further, in the method of producing the dope in the present invention may be used a mixture solvent of halogenated hydrocarbons (dichloromethane and the like) or that of halogenated hydrocarbons and other solvents.

[Polymer]

The polymers to be used in the present invention is not restricted especially. Concretely, there are polyamides, polyolefines, norbornenes, polystyrenes, polycarbonates, polysulfones, polyacrylates, polymehtacrylates, polyetheretherketones (PEEK), polyvinyl alcohols, polyvinyl acetates, cellulose derivatives (lower aliphatic acid esters of cellulose, cellulose acylate and the like).

It is preferable to use cellulose acylate as a derivative of cellulose, and particularly to use lower aliphatic acid ester of cellulose, whose explanation will be made in followings.

A lower aliphatic acid has at most 6 carbons. The preferable number of the carbon is 2 (cellulose acetate), 3 (cellulosepropionate) or 4 (cellulosebutylate). The cellulose acetate is particularly preferable and the cellulose triacetate (Acetification degree: 59.0-62.5%) is especially preferable. Note that the cellulose triacetate is made of cotton linter or wood pulp. Single one or mixture of these cellulose acylates may be used.

When the TAC is used as the polymer, it is preferable in view of influences on a circumstance to use the mixture solvent whose main solvent is methyl acetylate. In this case, the composition ratio of the methyl acetate in the mixture solvent is preferable at least 60 wt. %, and especially at least 70 wt. %. Only the methyl acetate may be used (100%). Further, it is the most preferable to mix methyl acetate to the other solvent, since the physical properties of the dopes can be controlled. As the other solvents, there are alcohols (methanol, ethanol and the like), ketones (cyclopentanone, acetone and the like).

[Additives]

Additives well known can be used as additives of the dope. For example, there are plasticizers (triphenyl phosphate (herein after TPP), biphenyldiphenyl phosphate, dipentaerythritol hexaacetate and the like) ultraviolet absorbing agents (oxybenzophenone type compounds, benzotriazole type compounds and the like), matting agents (silicone dioxide and the like), thickners, oil gelation agents and the like. However, the additives are not restricted in them. The additives may be added when the dope is prepared in the cool-dissolving method, or when the film is produced in a solution casting method from the dope prepared from the polymer and the solvent.

[Dope Production Method]

(Swelling Process)

In the swelling process, the polymers are mixed with the solvent so as to swell therein. The temperature in the swelling process is preferably set from −10° C. to 55° C., and usually at a room temperature. The rate of the polymers to the solvent is determined according to the density of the solution to be obtained. Usually, the preferable density of the polymers is from 5 wt. % to 30 wt. % of the solution, particularly from 8 wt. % to 20 wt. %, especially from 10 wt. % to 15 wt. %. Preferably, an unmodified solution as a mixture of the polymers and the solvents is stirred for 10-150 minutes, particularly 20-120 minutes, such that the polymers may swell enough. In the swelling process, other components may be also added, for example, plasticizers, anti-deterioration agent, ultraviolet stabilizers than the polymer and the solvents.

(Dope Production Apparatus)

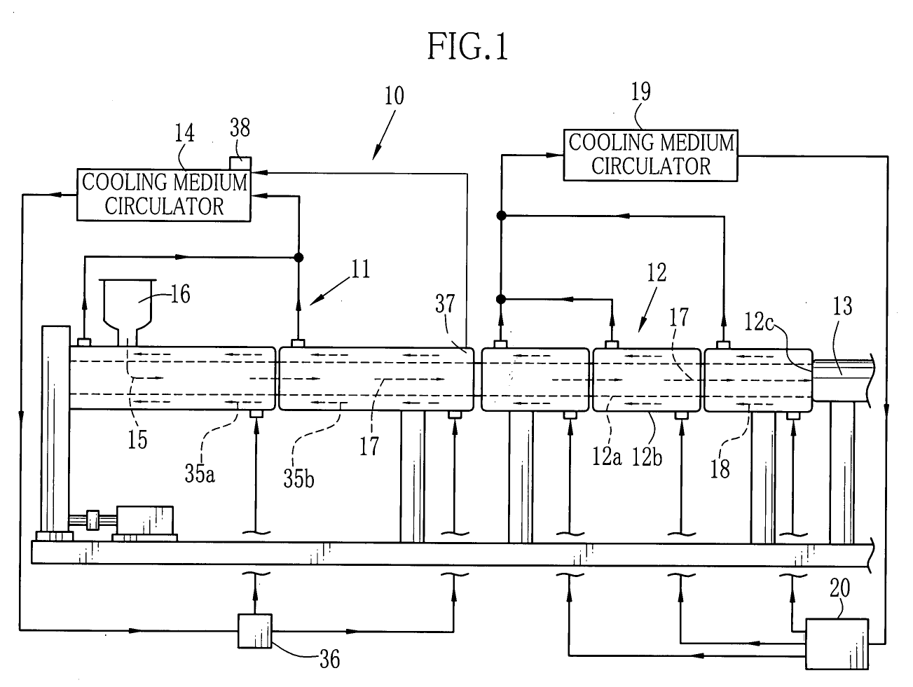

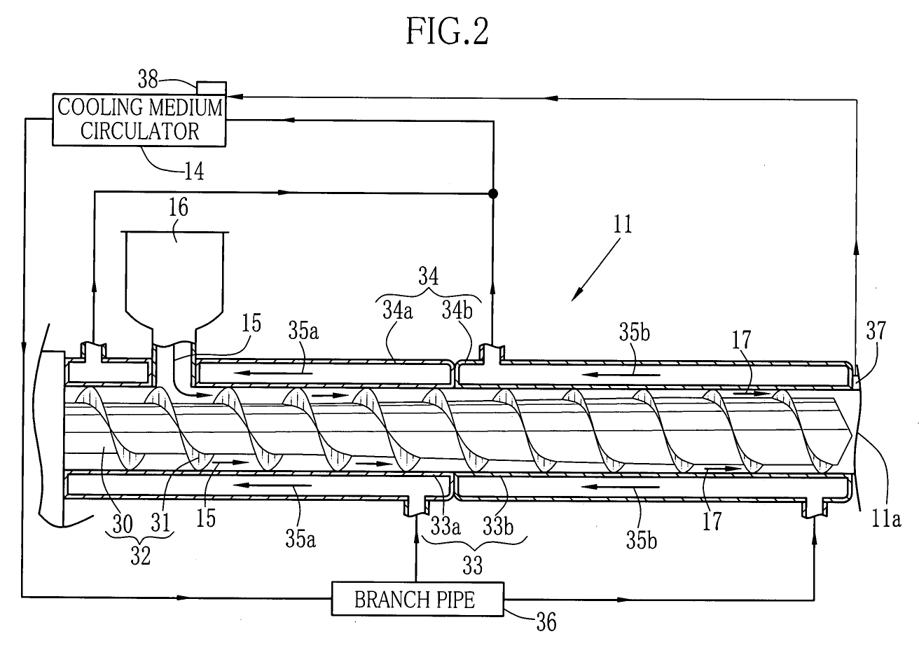

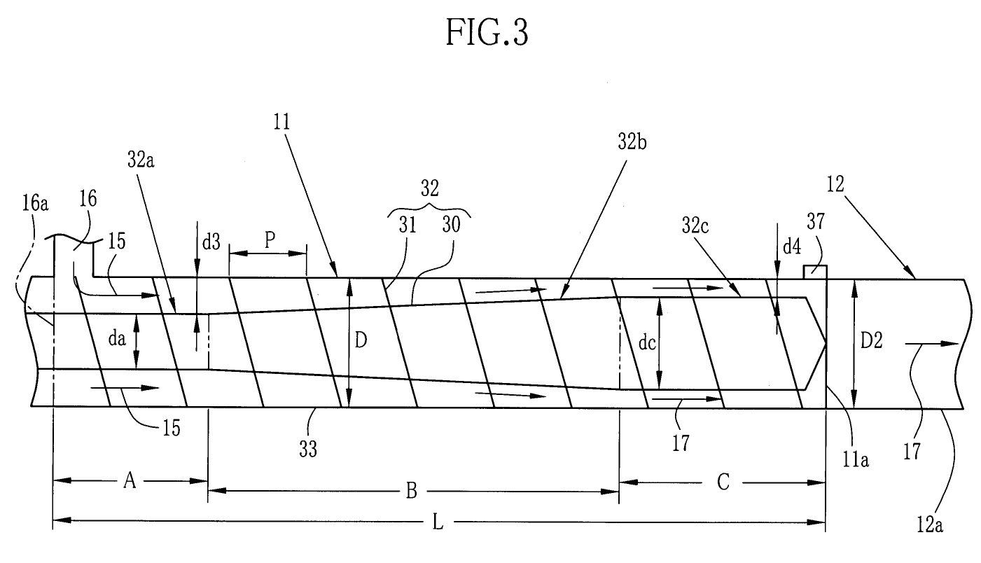

In FIG. 1, a dope production apparatus 10 used in a method of preparing the dope is illustrated. In FIG. 2, a sectional view of the dope production apparatus is illustrated. In FIG. 3, a partial diagrammatic view of the film production apparatus is illustrated. In the dope production apparatus 10, there are an extrusion machine 11 of a single shaft type, the cooler 12 and a heater 13. Further, a cooling medium circulator 14 for circulating a cooling medium, a hopper 16 into which are supplied the raw materials of the dope or the swelling solution is attached to the extrusion machine 11. The raw materials of the dope are solute including additives to be added if necessary a polymer and a solvent (it may be mixture solvent). Further, in the explanation below, a unmodified solution 15 is produced from raw material in the above mixing and swelling process. Note that a unmodified solution 15 contains the TAC as the polymer and methyl acetate as the solvent (composition ratio is 30 wt. % to 98 wt. %). However, the unmodified solution 15 is not restricted in this embodiment.

(Cool-dissolving Process)

The unmodified solution 15 is fed from a hopper 16 in the extrusion machine 11. Then the unmodified solution 15 is cooled and mixed with application of the high pressure thereto in the extrusion machine. Thus a dope 17 is obtained. Note that in the present invention, the unmodified solution is determined as a mixed material for the dope preparation, which includes a solution in which the swelling is made, and the dope is determined to a solution or a dispersion in which the solute is dissolved to or dispersed in the solvent. When the part of the solute is dissolved, one of the unmodified solution 15 and the dope 17 is used. However, when the explanation is not made, the part of the solute is dissolved to the solvent in the extrusion machine 11.

As shown in FIG. 2, the extrusion machine 11 includes a cylinder 33 and a screw 32 provided in the cylinder 33. The cylinder 33 has a screw shaft 30 and a flight 31 formed to the screw shaft 30. In a periphery of the cylinder 33, a jacket 34 is provided. In the present invention, in order to regulate the temperature of the unmodified solution 15 or the dope 17 in the cylinder 33, the jacket 34 is partitioned. Thus the temperature is controlled so as to feed the unmodified solution 15 or the dope 17 effectively. When the temperature of the cylinder 33 is controlled, the feeding conditions of the unmodified solution 15 or the dope 17 are adequately adjusted, which improve the productivity. In FIG. 2 there are a first section 34a (in entrance side) and a second section 34b (in exit side). However, more than three partitions may be provided in the present invention.

A thermometer 37 is attached to a side of an exit 11a of the extrusion machine 11 for measuring the temperature TD(° C.) of the dope at the exit 11a. On the basis of the data of the measurement, a controller 38 controls the cooling medium circulator 14 such that the temperature of the dope may be the most adequate. For example, the temperature Td of the dope 17 at the exit 11a is preferably −30° C. However, in the present invention the temperature may be regulated according to the composition of the unmodified solution 15. Further, the control of the temperature is not restricted in automatic control by the controller 38, and may include that an operator reads the measured value of the thermometer to adequately change the conditions.

Cooling mediums 35a, 35b are feed through the respective first and second sections 34a, 34b of the jacket 34 to cool the cylinder 33. Thus the unmodified solution 15 or the dope 17 in the cylinder 33 is cooled. The cooing mediums 35a, 35b are not restricted especially. However it may be methanol, hydrof luoro ethers, brine (trade name) and the like. There are trade names of the hydrofluoro ethers, for example, HFE7100, HFE7200 and the like. Note that in the present invention, the temperature of the cooling mediums 35a, 35b fed through the jackets are regarded as a jacket temperature, which is further regarded as the cooling temperature of the unmodified solution 15 or the dope 17.

In the present invention, a cooling speed of the unmodified solution 15 or the dope 17 in the extrusion machine 11 is preferably in the range of 5° C./min to 200° C./min. In the extrusion machine 11, the cooling speed is calculated by the temperature TD(° C.), a temperature TO(° C.) of the unmodified solution 15 supplied into the cylinder 33, a flowing period of the unmodified solution 15 or the dope 17 in the extrusion machine 11, and a cooling period Tc for which the unmodified solution 15 or the dope stays in the extrusion machine. Concretely, the cooling speed is determined to the formula:

(TD−T0)/Tc.

A feeding speed of the cooling mediums 35a, 35b is preferably regulated in the range of 0.1 m/s to 50 m/s, such that the unmodified solution 15 or the dope 17 may be cooled at the cooling speed in the range of 5° C./min to 200° C./min. In this case the solubility becomes higher. However, the cooling mediums 35a, 35b are not restricted in the above feeding speed. Note that in view of the cooling efficiency, it is preferable to feed the cooling mediums 35a, 35b in an opposite direction to the feeding direction of the unmodified solution 15 or the dope 17. However, the cooling mediums and the unmodified solution 15 or the dope may be fed in the same direction.

When the temperature of the second section 34b of the jacket 34 is lower than that of the first section 34a, the relation of the temperature T1 at an entrance 33a of the cylinder 33 to the temperature T2 at an exit is T2<T1. In this case, when the solute such as the polymer is not dissolved to the solvent, the moderate cooling is made to feed the unmodified solution 15 or the dope, and when the dissolution is progressed and the feeding becomes easy, the cooling temperature is set to lower one to make the dissolution moreover. Concretely, the temperature T1 at the entrance of the cylinder is in the range of −30° C. to 5° C., and the temperature T2 at the exit is in the range of −100° C. to −30° C. However, the cooling temperature is not restricted in them.

After flowing in the first and second sections 34a, 34b, the cooling medium 35a, 35b are fed to the cooling medium circulator 14. The cooling mediums 35a, 35b whose each temperature became higher therebefore are cooled by the cooling medium circulator 14, and then supplied through the branch pipe 36 into the first and second sections 34a, 34b. Since the cooling mediums 35a, 35b are cyclically used, they are not discharged into the atmosphere, and therefore there are no influences of them on the circumstance but merits in the point of the cost. However, the cooling medium circulator 14 may be omitted in the present invention. In FIG. 2, the feeding is made through a branch pipe 36 to the first and second sections 34a, 34b. However, the first and second sections 34a, 34b are respectively connected through pipes to two circulators. Further, the cooling medium circulator 14 feeds out the cooling medium 35 to the second section 34b, and thereafter the cooling medium 35 from the second section 34b is fed to the first section 34a, and thereafter, the cooling medium 35 may be fed back to the cooing medium circulator 14.

A screw 32 is used in the present invention, and as shown in FIG. 3, the screw 32 is constructed of a first portion 32a disposed so as to confront to an entrance from the hopper 16, a second portion 32b for applying a pressure to the unmodified solution 15, and a third portion 32c for feeding out the dope 17. The third portion 32c is a measurement portion for performing several measurements. The diameter of the second portion 32b becomes larger from a side of the first portion 32a to a side of the third portion 32c. The space to the cylinder 33 becomes narrower in the feeding direction of the unmodified solution 15 or the dope 17. Further, the diameter da (mm) of the screw shaft of the first portion 32a has a following relation to a diameter dc(mm) of that of the third portion 32c:

da<dc (F-1)

Thus the unmodified solution 15 or the dope 17 is compressed. Concretely, the inner diameter D of the cylinder 33 is 100 mm, and a channel depth d3 in the first portion is from 2 mm to 20 mm. Further, a channel depth d4 in the third portion is 1 mm to 9 mm, a diameter da of the first portion is 60 mm to 96 mm, and a diameter dc of the third portion is from 82 mm to 98 mm. However, the present invention is not restricted in these ranges. Further, a pitch P of the flight 31 is preferably at least D/3 and at most 3×D. However, the pitch is not restricted in this range.

The first-third portions 32a-32c have respective lengths A(mm), B(mm), C(mm), and it is preferable to satisfy the condition:

A≦B and C≦B (F-2)

In this case, the volumetric efficiency of the unmodified solution 15 becomes larger, to produce the dope 17 more effectively. Further, the lengths A, B, C preferably satisfy the conditions:

1.1≦(B/A)≦4, and 1.1≦(B/C)≦4 (F-3)

In this case, the effect becomes almost the same as the condition of F-2. Further, theoretic discharge rate for one rotation number is obtained from a theoretic value which is calculated from a channel depth on the screw. When the two conditions of (F-2)&(F-3) are satisfied at the same time, the discharge rate of the dope from the screw 32 becomes closer to the theoretic discharge rate, and the discharge rate in the one rotation number becomes the largest. This is called the increase of the volumetric efficiency in low viscosity. In order to increase the volumetric efficiency in low viscosity, the lengths A, B, C of the respective first-third portions are not restricted. Preferably, the length A of the first portion is 180 mm to 1200 mm, the length B of the second portion is 710 mm to 1330 mm, and the length C of the third portion is 180 mm to 1200 mm. However, the present invention is not restricted in these ranges. Note that an origin of the length A of the first portion 32a is a hopper edge 16a which is a most upstream point of the connection part to the hopper 16. Further, the screw 32 can be produced by using the well known method of producing the screw.

The motor (not shown) is driven to rotate the screw 32 in the cylinder 33. When the unmodified solution 15 is supplied from the hopper 16 to the cylinder 33, then the mixing with compression of the unmodified solution 15 is made sequentially in first-third portions 32a-32c. Thus the dissolution is progressed gradually. In accordance with the rotation of the flight 31, the unmodified solution 15 is pressed from the first portion 32a to the second portion 32b whose sectional area is small. In the second portion 32b, the sectional area for the feeding becomes smaller in the side of the exit 11a of the extrusion machine 11. Accordingly, the unmodified solution 15 or the dope 17 is compressed. Then in the third portion 32c, the dissolution in the unmodified solution 15 is progressed to obtain the uniform dope 17. Usually, the exothermic heat is generated in the dissolution of the solute or the compression of the liquid. However, as the cooling mediums 35a, 35b make the cooling so as to keep the temperature in the cylinder 33 constant. Therefore even though the pressure in the cylinder 33 becomes higher, the rotation number of the screw 32 can be decreased. Further, when the cooling efficiency becomes lower, the rotation number of the screw may be made lower in order to make the cooling period longer. However, when the temperature in the cylinder 33 is kept constant, it is not necessary to reduce the rotation number. Furthermore, in the present invention, the preferable range of the pressure in the cylinder 33 doesn't have any relation to that of the rotation number of the screw. They can be determined adequately depending to other conditions.

In the present invention, a center of the section of the cylinder 33 may be positioned on a rotary axis of the screw shaft 30. In this case, there is a space between the screw shaft 30 and the cylinder 33, and the space is called channel depth. Concretely, a channel depth d3(mm) around the first portion is preferably from 2 mm to 20 mm, and a channel depth d4(mm) around the third portion is preferably from 1 mm to 9 mm and especially from 1.5 mm to 6 mm. However, The channel depths are not restricted in these ranges.

In the present invention, the compression of the unmodified solution 15 or the dope 17 depends on a rate d3/d4 of the channel depths between the first and third portions 32a,32c. The rate is named compression rate. The compression rate is preferably more than 1.0 and at most 5. However, the compression rate is not restricted in this range. When it is at most 1.0, the unmodified solution 15 cannot be compressed, it often becomes hard that the productivity of the dope 17 becomes higher. Further when the compression rate is more than 5, it often becomes hard to rotate the screw 32 at the constant rotating speed, and sometimes the screw 32 cannot be rotated. Further, when the compression rate is large, the pressure in the cylinder 33 increases to break the cylinder 33. Further, the higher compression rate sometimes decreases the solubility in the cooling.

Further, in the present invention, a length L(mm) of a leading portion of the extrusion machine 11 and an inner diameter D(mm) of the cylinder satisfy the condition:

5<(L/D)<50 (F-4)

Thus the dope 17 can be effectively produced. Note that the origin of the leading portion is the hopper edge 16a, the same as that of the first portion. An end of the leading portion is the most downstream point confronting to the exit 11a. When (L/D) is at most 5, the length for cool-dissolving the unmodified solution 15 becomes shorter. In order to produce the dope, it is necessary to make the rotation speed of the screw lower such that the feeding speed of the unmodified solution 15 in the cylinder 33 may become lower. When the feeding speed becomes lower, the productivity of the dope sometimes becomes lower. Further, when (L/D) is at least 50, the screw 32 becomes longer, and it becomes harder to keep an area to set the extrusion machine 11. Further, the cost for production of the extrusion machine 11 becomes higher. Thus it is often not preferable. Accordingly, the length L of the leading portion is in the range of 150 mm to 20000 mm, and the inner diameter D of the cylinder 33 is in the range of 30 mm to 400 mm. However, the values are not restricted in these ranges.

Note in the present invention that the extrusion machine may have other embodiment than the illustrated one, in order to improve the productivity of the dope 17 with compression of the unmodified solution 15. For example, the pitch P of the flight may be formed so as to become narrower from the first portion to the third portion. Thus the unmodified solution 15 is compressed for producing the dope. Further, the extrusion machine used in the present invention is not restricted in that including the screw of the single shaft type., but may be the screw of double shaft type. The double shaft type is preferable in view of increase of the solubility. Further, in the present invention the embodiment of the screw in the extrusion machine is not restricted in the compression type, but may be applied to a dope production apparatus in which a cooler is provided in a downstream side of the extrusion machine of the prior art. In this case, the energy consumption of the screw for keeping the cooling temperature is large. However since the area of such screw becomes shorter, the energy consumption is reduced. Further, the solubility of the dope is increased by the cooler in the downstream side, and therefore the high quality dope containing the undissolved materials can be obtained.

(Low Temperature Keeping Process)

The dope 17 cooled in the extrusion machine is fed to the cooler 12, and the dissolution is preferably made more. The cooler 12 is such a double type pipe that the feeding resistance of the dope 17 may be decreased. In the present invention, an outer pipe 12b is preferable into plural sections. In FIG. 1, the outer pipe 12b is separated into three sections, such that the temperature control can be independently made in each section. The cooling medium 18 is fed through the outer pipe 12b to cool the dope 17 in an inner pipe 12a. Thus the dope 17 is cooled in the inner pipe 12a. When the cooler 12 is used, the cooling period becomes longer, and thus the solubility of the dope 17 is improved. Thus the productivity of the dope becomes larger. In the present invention, the period for cooling the dope 17 in the cooler 12 is preferably at most 60 minutes for improving the productivity. When the period is longer than 60 minutes, the solubility is not improved so much and the cost becomes higher. However, in the present invention, the cooling period may be more than 60 minutes depending on a composition of the unmodified solution 15.

The cooling medium 18 discharged from the cooler 12 is fed through a branch pipe 20 to the cooling medium circulator 19. In point of the circumstance maintenance, it is preferable that the cooling medium circulator 19 cools the cooling medium 18 whose temperature has become higher. Thus the quantity of the cooling medium to be used is made lower, and the amount of the cooling medium emitted into the atmosphere becomes extremely small. The cooling medium used in the present invention is not restricted especially. However, the preferable cooing medium is methanol, hydrofluoro ethers, brine (trade name), and the like, and the expecially preferable one is fluorinate (trade name) which is one of hydrof luoro ethers. Note that the cooling medium circulators 14, 19 may not independently provided for the extrusion machine 11 and the cooler 12, but only one cooling medium temperature may be provided for the extrusion machine 11 and the cooler 12.

A volume V1 in the extrusion machine 11 and a volume V2 in the cooler 12 preferably satisfy the condition;

0.5≦(V2/V1)≦100 (F-5)

When the rate V2/V1 is less than 0.5, the cooling period in the cooler 12 becomes shorter. Accordingly, in this case, the effects of the present invention for the improvement of the solubility are often not enough. Further, the rate is larger than 100, the cooler 12 becomes too large to keep a setting area, and the cost becomes higher. Concretely the volume V1 in the extrusion machine is in the range of 0.2×10⁻³m³ to 50×10⁻³m³, and the volume V2 in the cooler is in the range of 0.1×10⁻³m³ to 50×10⁻¹m³. The rate (V2/V1) is preferably 0.5≦(V2/V1)≦100, particularly 0.7≦(V2/V1)≦50, and. especially 1≦(V2/V1)≦5.

An inner diameter D (mm) of the extrusion machine 11 and an inner diameter D2(mm) of the inner pipe 12a preferably satisfy the condition;

0.8<(D2/D)<10 (F-6)

When the rate D2/D is less than 0.8, the inner diameter D2 of the inner pipe 12a is much smaller than the inner diameter D of the cylinder. Accordingly, when the dope 17 is fed to the cooler 12, the pressure becomes too high to keep the dope feeding speed constant. Further, when the rate is not in the above range, the cost becomes higher, or the apparatus is too large. Further the large area is necessary for setting the apparatus. Further, when several pipes of different diameters are used as the inner and outer tubes 12a, 12c and the cylinder 33, the centers of them are positioned on a line. In this case, when the rate D2/D is more than 10, the cost sometimes becomes high. Concretely, when the inner diameter D of the cylinder is in the range of 50 mm to 500 mm, and the inner diameter D2 of the inner pipe is in the range of 40 mm to 5000 mm, the rate D2/D is preferably 0.8<(D2/D)<10, particularly 0.9<(D2/D)<5, and especially 1<(D2/D)<3.

As the temperature of the extrusion machine 11 and the cooler 12 in the dope production apparatus 10 is controlled, the productivity of the dope 17 from the unmodified solution 15 becomes high. In order to make the productivity higher, the dope 17 in the extrusion machine 11 is preferably cooled more. However, when the length L of the leading portion of the extrusion machine 11 is large, the cost becomes high. Accordingly, the cooler 12 for keeping the cooling temperature of the dope 17 in the extrusion machine 11 is preferably provided in a downstream side of the dope production apparatus 10. In the dope 17 fed in the cooler 12, the dissolution is progressed in effect of the mixing of the extrusion machine 11. Therefore, the cooler 12 may be a cooling zone, and shorter than the length L of the leading portion of the extrusion machine 11. In this case, the cost is low and preferable. The dope 17 in the cooler 12 is cooled and thus the solubility is kept and further progressed. Note that in this case a temperature T(° C.) of the inner pipe 12a of the cooler and a temperature T2(° C.) at the exit of the cylinder preferably satisfy the condition:

T≦T2 (F-7′)

and especially the condition:

T≦0.95×T2 (F-7)

Concretely, the temperature T(° C.) is preferably in the range of −85≦T(° C.)≦−30. However, the present invention is not restricted in this range.

In the dope production apparatus 10 of the present invention, the temperature of the dope 17 or the unmodified solution 15 preferably becomes higher from the downstream to the upstream side. Otherwise, the temperature may be controlled so as to be in the opposite situation. Namely, the temperature may become higher from the upstream to the downstream side. The cooling mediums are fed in sectioned outer pipes 12b and first and second sections 34a, 34b sequentially, such that the downstream side may be cooled the most, and the temperature becomes higher in the upstream side. In this case, the cooling is made with one cooling medium circulator instead of the cooling medium circulators 14,19 (FIG. 1), and the quantity of the cooling mediums becomes smaller. Further, as the dope production apparatus 10 is easily constructed, there is a merit in cost. Furthermore, the medium may be fed at first at the lowest temperature in the second section 34b, and then in the outer pipe 12b, and in the first section 34a at last.

At an exit 12c, the dope 17 is cooled extremely, and the temperature thereby is preferably in the range of −85° C. to −30° C. However, the present invention is not restricted in this range. When the dope 17 is disposed in the atmosphere, the moisture in the atmosphere is not only solidified but also makes the physical properties of the dope worse. Accordingly, it is preferable in the present invention that the heater 13 for heating the dope 17 is connected directly to the cooler 12. Further, the heating of the dope 17 improves the solubility. However, the heater 13 may be omitted in the dope production apparatus 10 of the present invention. In this case, the dope discharged from the exit 12c is kept in a cooling tank (not shown) in which the inner temperature is regulated, and the heating is made in the film producing process which will be described below. Note that the heating process with the heater 13 will be explained below.

When the dope 17 prepared by compressing the unmodified solution 15 has the predetermined solubility, the cooler 12 may be omitted from the dope production apparatus 10. Further, also the embodiment in which the cooler 12 is not provided may be used. For example, the length C of the third portion in the extrusion machine 11 is made longer such that the dope 17 prepared in the second portion 32b may be uniform in the third portion 32c. Further, the extrusion machine 11 may be provided integrally with a cylindrical cool-feeding member (not shown) in which the screw 32 is not provided in the downstream side of the third portion 32c. And the rotation of the screw 32 increases the pressure. However, the cooling temperature may be kept by reducing the influences of the increasing pressure.

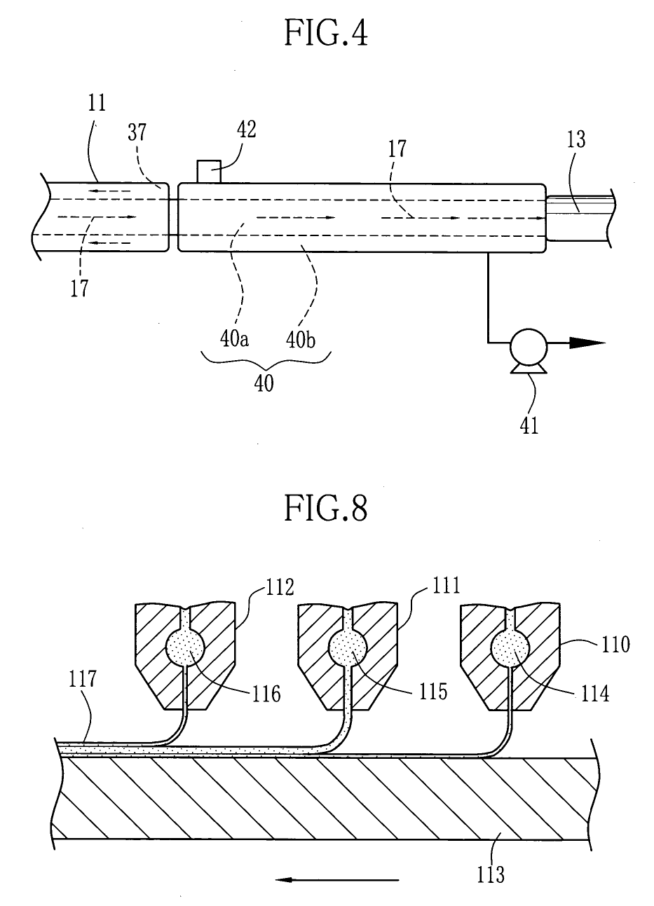

As shown in FIG. 4, instead of the cooler 12, a cooler 40 may be used, which includes an inner pipe 40a for feeding the dope 17 therein and an outer pipe 40b. The aspiration of an inner side of the outer pipe 40b is made with a vacuum pump 41, and the outer pipe 40b has a vacuum insulation structure. The degree of vacuum in the outer pipe 40b is measured with a pressure gauge 42, and preferably in the range of 0.5×10⁻³Pa to 5×10⁻³Pa. Since the outer area around the inner pipe 40a in which the dope 17 is fed is vacuum, it is prevented that the temperature of the dope becomes higher in the atmosphere of the room temperature, and the cooling temperature in the extrusion machine 11 is almost kept to obtain the same effect in the cooler 12. Note that the other structure of the cooler 40 than the suctioning is the same as that of the cooler 12.

Instead of the cooler 12 of the dope production apparatus 10, another extrusion machine (not shown) may be provided. The another extrusion machine is preferably the single shaft type or the double shaft type. The another extrusion machine has a cooling section such as jackets and the like the same as the extrusion machine 11 in FIG. 1. In this case, the dope obtained in the cool-dissolution by the extrusion machine 11 is mixed and cooled in the another extrusion machine to improve the solubility of the dope. Note that the another extrusion machine may be the same as or other than the extrusion machine 11. In the latter case it is preferable that the another extrusion machine is the same as the cooler for producing the dope uniformly. Namely, the volume V1 in the extrusion machine 11 and a volume V1′ in the another extrusion machine preferably satisfy the condition of 0.5≦(V1′/V1)≦100, and the inner diameter D of the extrusion machine 11 and an inner diameter D′ of the another extrusion machine preferably satisfy the condition of 0.8<(D′/D)<10. Note that the volume V1′ and the inner diameter D′ are not restricted in these ranges.

(Heating Process)

The dope 17 is fed to the heater 13 connected to the cooler 12, so as to increase the temperature suddenly. Thus the solubility becomes larger to obtain the dope uniformly. The heating conditions of the dope by the heater 13 are not restricted especially. However, the heating speed is preferably at least 20° C./min, particularly at least 30° C./min, and especially at least 40° C./min. Further, the heating period is preferably at most 60 minutes, preferably at most 30 minutes, and especially at most 10 minutes.

As described above, according to the method of producing the dope with use of the dope production apparatus 10 of the present invention, when the inner diameter D of the cylinder is 100 mm in the dope production apparatus 10, the dope in which the solute is dissolved to the solvent can be continuously produced with high productivity in the range of 0.5 kg/min to 10 kg/min.

(Process after Production of Dope)

To the produced dope, necessary processing is made, such as a density adjustment (condensation or dilution), a filtration, a temperature adjustment, an addition of components. The components to be added are determined depending on the use of the dope. The representative additives are plasticizer, deterioration inhibitor (for example peroxide decomposer, radical inhibitor, metal deactivator, acid capture, and the like), dye, and the UV-absorbing agent. It is necessary to keep the dope in a temperature range preferable for stability of the dope. For example, when the dope is prepared in the cool-dissolving method from cellulose acetate and methyl acetate as the main solvent, there are in practice two phase-separation ranges for keeping the dope in a high temperature area and a low temperature area. In order to keep the dope stably, it is necessary to keep the dope at the temperature between the higher and lower separation ranges. This temperature is in the constant phase region. The obtained dope is used in several ways. For example, the dope is fed to the film production apparatus to produce the film in the solution casting method.

[Solution Casting Method]

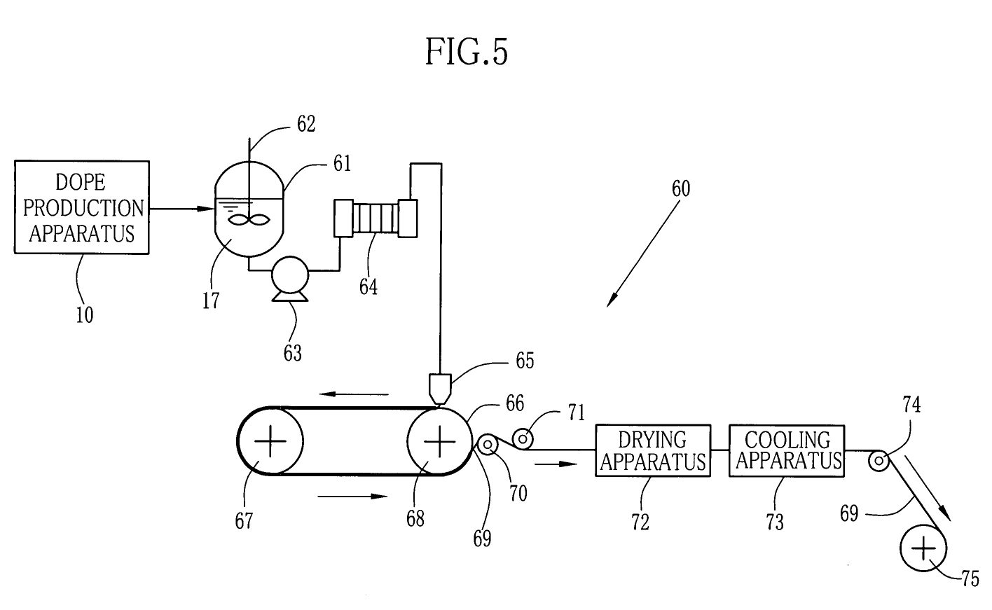

The production of the film in the solution casting method from the above dope will be explained. FIG. 5 illustrates a diagrammatic view of a film production apparatus 60 used in the present invention. Note that in this embodiment the polymer used for the dope is cellulose acylate. However, the present invention is not restricted in cellulose acylate. The dope obtained in the method of producing the dope of the present invention above described is contained in a mixing tank 61 to stir with a stirrer 62. Thereby, the additives may be added to the dope 17. The content of the solid material for the dope 17 is preferably in the range of 10 wt. % to 30 wt. %. The dope 17 is fed to a filtration device 64 at a constant low rate by the pump 63. After the impurities are removed, the dope 17 is fed to a casting die 65. Note that the filtration device 64 may be omitted in the present invention.

The dope 17 is cast from the casting die 65 onto the belt 66. Note that the temperature of the dope 17 thereby is preferably in the range of −50° C. to 80° C. However, the present invention is not restricted in it. The belt 66 is supported by rollers 67,68, and a driving device is driven to cyclically and endlessly move the belt 66. The casting speed (or the moving speed of the belt 66) is preferably in the range of 0.5 m/s to 2 m/s, since the film thickness becomes constant in the obtained film. However, the present invention is not restricted in this range. The solvent gradually evaporates from the dope 17 cast on the belt 66, and the dope 17 has the self-supporting properties to form the film 69. Note that the surface of the belt 66 preferably has a mirror finished surface. Furthermore, instead of the belt 66 a rotary drum may be used.

The film 69 is peeled from the belt 66 with use of a peeling roller 70, and transferred to a drying device 72 by rollers 71. According to the drying conditions of the drying device 72, it is preferable that the drying temperature is from 100° C. to 160° C., and that the drying period is from 5 minutes to 20 minutes. However, the present invention is not restricted in these ranges. Further, preferably, plural sections are provided in the drying device 72, and the drying conditions are adjusted depending on the content of the solvent in the film 69. Preferably, the film is fed to a cooler 73 to make the cooling thereof after the drying device 72. In this case, the film does not deformed when the film is wound. However, the cooler 73 may be omitted. Note that it is preferable to cool the film to the room temperature in the cooler 73. The temperature is not restricted. The film 69 discharged from the cooler 73 is transferred by a roller 74 and wound by a winding device 75. Note that a knurling or a cutting treatment of both side edges may be made between the cooler 73 and the winding device 75. Further, a tenter dryer may be made as the drying device for stretching the film 69. Further, the film 69 may be drawn in the feeding direction (or the lengthwise direction of the film) in the feeding before the dying.

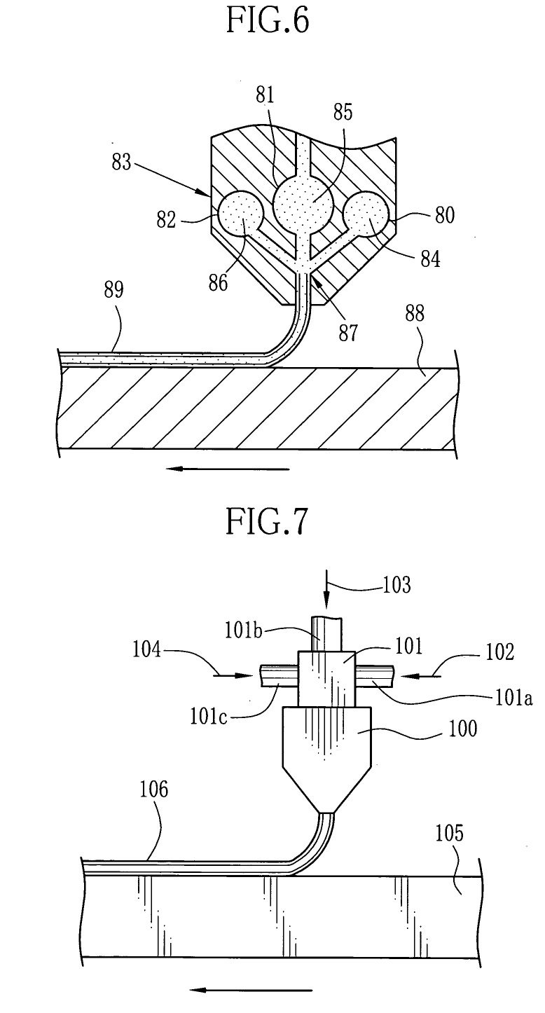

The solution casting method as a film production method of the present invention is not restricted in the above method. Other embodiments, especially those of the casting of plural dopes will be explained in followings with reference to FIGS. 6-8. Note that only the different points are explained in these figures, and the explanation for the same points will be omitted.

FIG. 6 is a sectional view of a casting die 83 of a multi-manifold type used in a co-casting method as the method of producing the film. The casting die 83 has manifolds 80-82 into which dopes 84-86 are supplied. (Pipes for supplying the dopes are not shown). The dopes 84-86 are joined at a joining point 87, and cast on a belt 88 to form a casting film 89. The casting film 89 is peeled as a film. Note that the film production speed becomes higher and the productivity will be improved, when the dope produced in the apparatus and the method of producing the dope of the present invention is used as at least one of the dopes supplied into the casting die 83. Especially preferably, all the three dopes 84-86 are the dopes produced in the apparatus and the method of producing the dope of the present invention.

FIG. 7 is a side view of another embodiment of the co-casting. A feed block 101 is attached to casting die 100 in an upstream side thereof. Pipes 101a-101c connect a dope feeding device (not shown) to the feed block so as to feed dopes 102-104. The dopes 102-104 are joined in the feed block 101, supplied into the casting die 100, and cast to form a casting film 106 on a belt 105. When having the self-supporting properties, the casting film 106 is peeled from the belt 105 and dried to obtain the film. Note that the film production speed becomes higher and the productivity will be improved, when the dope produced in the apparatus and the method of producing the dope of the present invention is used as at least one of the dopes supplied into the casting die 100 provided with the feed block 101. Especially preferably, all the three dopes 102-104 are the dopes produced in the apparatus and the method of producing the dope of the present invention. Note that a rotary drum may be used instead of the belts 88, 105 as the substrates in FIGS. 6 & 7.

FIG. 8 is an exploded sectional view of an embodiment of the sequential casting. Three casting dies 110-112 are disposed above a belt 113. A feeding device (not shown) supplies dopes 114-116 for the respective casting dies 110-112. The dopes 114-116 are cast on the belt 113 sequentially to form a casting film 117, and thereafter the casting film 117 is peeled as the film. Note that the film production speed becomes higher and the productivity will be improved, when the dope produced in the apparatus and the method of producing the dope of the present invention is used as at least one of the dopes supplied into the casting die 100 provided with the feed block 101. Especially preferably, all the three dopes 114-116 are the dopes produced in the apparatus and the method of producing the dope of the present invention.

As anther embodiment than the above ones, for example, a solution casting method of the present invention may include a hyper cooling casting method in which a rotary drum is cooled. Further, as at least one of the casting die in the sequential casting method illustrated in FIG. 8, the casting die of the multi-manifold type may be used. Otherwise the feed block may be provided in the upstream side of the casting die in the performance of the sequential casting method.

[Films]

The film obtained in one of the embodiments of the solution casting method is excellent in the uniform film thickness and the optical properties, since the dope is uniform. Further, as the productivity of the dope is high, the productivity of the film is excellent and there is a merit in view of the cost. Further, as the film base to be used has the excellent optical property, the protective film produced from the film base also has the excellent optical property. Further, when the protective films are adhered to both surfaces of a polarized film including polarizers, a polarizing filter having the excellent optical properties is produced. These products (for example, a polarizing filter, an optical compensation film, an antireflection film in which antiglare layers are formed on the film and the like) can construct a liquid crystal display. Further, photosensitive layers are formed on the film base to produce a photosensitive material.

Experiments with Examples were performed, and the explanation thereof will be made. The explanations about Example 1 will be made in detail, and the same explanations will be omitted according to Examples 2-5, 7-22 and Example 6 as a comparison. The conditions and the results of Examples, and the results of the estimation will be shown in Tables 1-8.

[Experiment 1]

[Production of Dope A]

Dope A was prepared from the following contents, and used in the following Examples when the specific explanations.

| | |
|---|---|
| (Polymer) | |
| Cellulose triacetate | 28 pts. wt. |
| (acetyl value was 2.83, viscometric average degree of | |
| polymerization was 320, moisture content was 0.4 wt. %, | |
| viscosity of 6% by mass of dichloromethane solution was | |
| 305 mPa · s.) | |
| (Solvent) | |
| Methyl acetate | 75 pts. wt. |
| Cyclopentanone | 10 pts. wt. |
| Acetone | 5 pts. wt. |
| Methanol | 5 pts. wt. |
| Ethanol | 5 pts. wt. |
| (Additives) | |
| Plasticizer A (dipentaerythritholhexaacetate) | 1 pts. wt. |
| Plasticizer B (Triphenyl phosphate; TPP) | 1 pts. wt. |
| Particles (silica having diameter of 20 nm) | 0.1 pts. wt. |
| UV-absorbing agent a | 0.1 pts. wt. |
| (2,4-bis-(n-octylthio)-6-(4-hydroxy-3,5-di-tert- | |
| butylanylino)-1,3,5-triazine) | |
| UV-absorbing agent b | 0.1 pts. wt. |
| (2-(2′-hydroxy-3′,5′-di-tert-butylphenyl)-5- | |
| chrolobenzotriazol) | |
| UV-absorbing agent c | 0.1 pts. wt. |
| (2-(2′-hydroxy-3′,5′-di-tert-amilphenyl)-5- | |
| chrolobenzotriazol) | |
| C₁₂H₂₅OCH₂CH₂O—P(═O)—(OK)₂ | 0.05 pts. wt. |

[Estimation of Produced Dope]

Estimation of the Dope A is prepared in each Example as explained later is made with eyes with following criterions into 6 grades. Note that a sample of the dope was contained in a glass bottle, and a light is applied thereto for determining in the observation how large amount of the undissolved particles remain therein. Note that the silica particles which are undissolvend materials have too small diameter and therefore are not observed with eyes. Further they have no influence on the present invention.

A: Extremely Excellent

B: Excellent

C: Good

N: Bad

Note that the silica particles having the small diameter are not observed with eyes, and have no influence on the estimations.

### EXAMPLE 1

In Example 1, the compression rate and the number of the screw shaft were varied. The dope was prepared with use of the extrusion machine 11 in which the screw was the compression type. In order to produce the Dope A, the solute containing the polymer and the additives was mixed to the mixture solvent so as to obtain the unmodified solution 15. The unmodified solution 15 was preserved in the hopper 16, and thereafter fed from it to the extrusion machine 11 of the single shaft type. Thereby the temperature T0 of the unmodified solution 15 was 30° C. According to the screw 32, the length A of the first portion 32a and the height of the flight therein are respectively 250 mm and 6 mm, the length B was 500 mm, and the length C of the first portion 32a and the height of the flight therein are respectively 250 mm and 3 mm. Thus the shape of the screw 32 satisfied the conditions; A≦B, B≦C, B/A=2.0, B/C=2.0. The inner diameter D of the cylinder 33 was 30 mm, the rate of the flight L to the inner diameter D, namely L/D, was 33.3. Further, the jacket 24 provided for the periphery of the cylinder was partitioned in two sections. The cooling medium (Frorinart; trade name) of the temperature at −45° C. was fed to the first section 34a, and the cooling medium (Frorinart; trade name) of the temperature at −70° C. was fed to the second section 34b. The temperature T1 at the entrance of the cylinder was −45° C., and the temperature T2 at the exit of the cylinder was −70° C. The rotational speed of the screw 32 was kept at 7 rpm. Thus the cool-dissolving was made. The flow rate of the produced dope was 50 g/min. Thereby the temperature TD of the dope 17 at the exit 11a of the extrusion machine 11 was −69.9° C.

Experiments 2&3 and Experiment 6 as a comparison were made in conditions illustrated in Table 1. Note that the extrusion machine of the double shaft type was used in Experiments 4&5. As the double shaft type, the used screw extruder was the mesh type, and the rotational direction was the same. Further, the extrusion type of the double shaft type was used in the same condition in Experiments 4 as Experiment 6, and the extrusion type of the double shaft type was used in the same condition in Experiments 5 as Experiment 2. Table 1 shows the experimental conditions and the results of estimation.

TABLE 1

| | 1^{st} Port. | | 2^{nd} Port. | 3^{rd} Port. | | | | |
|---|---|---|---|---|---|---|---|---|
| | Length | Height | Length | Length | Height | | | |
| | A(mm) | d3(mm) | B(mm) | C(mm) | d4(mm) | CR | SN | Sol. |
| Ex. 1 | 250 | 6 | 500 | 250 | 3 | 2.0 | 1 | B |
| Ex. 2 | 250 | 4 | 500 | 250 | 3 | 1.3 | 1 | C |
| Ex. 3 | 250 | 16 | 500 | 250 | 3 | 5.3 | 1 | C |
| Ex. 4 | 250 | 3 | 500 | 250 | 3 | 1.0 | 2 | C |
| Ex. 5 | 250 | 4 | 500 | 250 | 3 | 1.3 | 2 | A |
| Ex. 6 | 250 | 3 | 500 | 250 | 3 | 1.0 | 1 | N |

Port.: Portion
CR: Compression Rate
SN: Shaft Number
Sol.: Solubility

According to Table 1, the solubility was improved since the compression of the unmodified solution 15 or the dope 17 was made with the extrusion machine 11. Especially, in Experiment 1, the compression rate was 2.0, and the excellent dope was obtained (estimation B). Further, in the present invention, the extrusion machine of the double shaft type may be used (in Experiments 4&5), and in this case the solubility was improved. Further, in Examination 4, the double shaft type was used and the compression rate was 1.0, and the good dope was obtained (estimation C). Thus the same effects can be obtained with used of the double shaft type.

### EXAMPLE 2

In Example 2, the height d4 of the flight in the third portion was varied. Other condition was the same as Experiment 1. In Experiment 7 the height d4 was 1.4 mm, and in Experiment 8 the height d4 was 7 mm. Table 2-1,2-2 shows the experimental conditions and the results of estimation.

TABLE 2-1

| | Inner Diameter D(mm) | Value of L/D |
|---|---|---|
| Ex. 1 | 30 | 33.3 |
| Ex. 7 | 30 | 33.3 |
| Ex. 8 | 100 | 20.0 |
| Ex. 6 | 30 | 33.3 |

TABLE 2-2

| | 1^{st} Port. | | 2^{nd} Port. | 3^{rd} Port. | | | |
|---|---|---|---|---|---|---|---|
| | Length | Height | Length | Length | Height | | |
| | A(mm) | d3(mm) | B(mm) | C(mm) | d4(mm) | CR | Sol. |
| Ex. 1 | 250 | 6 | 500 | 250 | 3 | 2.0 | B |
| Ex. 7 | 250 | 7 | 500 | 250 | 1.4 | 5.0 | C |
| Ex. 8 | 500 | 14 | 1000 | 500 | 7 | 2.0 | C |
| Ex. 6 | 250 | 3 | 500 | 250 | 3 | 1.0 | N |

According to Table 2, when the compression rate is larger than 1 and at most 5, the solubility of the dope is increased. When the height d4 of the third portion was 3 mm (Experiment 1), the good dope was obtained (estimation B).

### EXAMPLE 3

In Experiment 9, the shape of the screw 32 was varied. Other condition was the same as Example 1. The inner diameter D of the cylinder was 100 mm, and the rate of the flight L to the inner diameter D, namely L/D, was 20.0. The length A of the first portion 32a and the height d3 of the flight therein are respectively 666 mm and 6 mm, the length B was 666 mm, and the length C of the third portion 32a and the height d4 of the flight therein are respectively 666 mm and 3 mm. Thus the shape of the screw 32 satisfied the conditions; A≦B, B≦C, B/A=1.0, B/C=1.0. Table 3-1, 3-2, 3-3 shows the experimental conditions and the results of estimation.

TABLE 3-1

| | Inner Diameter D(mm) | Value of L/D |
|---|---|---|
| Ex. 1 | 30 | 33.3 |
| Ex. 9 | 100 | 20.0 |

TABLE 3-2

| | | |
|---|---|---|
| 1^{st} Port. | 2^{nd} Port. | 3^{rd} Port. |

| | Length | Height | Length | Length | Height |
|---|---|---|---|---|---|
| | A(mm) | d3(mm) | B(mm) | C(mm) | d4(mm) |
| Ex. 1 | 250 | 6 | 500 | 250 | 3 |
| Ex. 9 | 666 | 6 | 666 | 666 | 3 |

TABLE 3-3

| | B/A | B/C | CR | Sol. |
|---|---|---|---|---|
| Ex. 1 | 2.0 | 2.0 | 2.0 | B |
| Ex. 9 | 1.0 | 1.0 | 2.0 | C |

According to these tables, the effects of compressing the dope with the compression of the present invention become larger in Experiment 9, although the length B for compressing is shorter than Experiment 1 (B/A=1.0, B/C=1.0).

### EXAMPLE 4

In Example 4, the condition of cooling the cylinder 33 was varied to perform Experiment 10&11. Other conditions were the same as in Examination 1. In Experiment 10, the jacket provided to the cylinder 33 was not partitioned. The cooling medium (Frorinart; trade name) of the temperature at −70° C. was fed to the jacket, such that the temperature of the cylinder might be −70° C. In Experiment 11, the jacket 24 provided for the periphery of the cylinder was partitioned in two sections 34a, 34b, and the cooling medium (Frorinart; trade name) of the temperature at −45° C. was fed to the both sections 34a, 34b. Thus the temperature T1 at the entrance of the cylinder and the temperature T2 at the exit of the cylinder were −45° C. Table 4 shows the experimental conditions and the results of estimation.

TABLE 4

Temperature of cylinder

| | Entrance | Exit | |
|---|---|---|---|
| | T1(° C.) | T2(° C.) | Sol. |
| Ex. 1 | −45 | −70 | B |
| Ex. 10 | −70 | −70 | C |
| Ex. 11 | −45 | −45 | C |

According to Table 4, when the temperature T1 at the entrance was −45° C. and the temperature T2 at the exit was −70° C. (Experiment 1), the excellent dope was obtained (estimation B). The reason therefor may be that the cooling temperature of the unmodified solution 15 is set to −45° C. as a higher value and the cooling temperature is set to −70° C. as a higher value after the progress of the dissolution, such that the dope was easily fed and the dissolution was further made.

### EXAMPLE 5

The feeding speed Sf and cooling speed Sc of the unmodified solution 15 (or the dope) in the extrusion machine 11 were varied. In Experiment 1, the rotation number of the screw 32 was adjusted such that the feeding speed might be 5×10⁻⁵m³/min. Thereby the flow rate (or a production speed Sp) of the produced dope was 50 g/min. Further, the volume V1 in the extrusion machine 11 was 35×10⁻⁵m³. A cooling period for which the unmodified solution 15 or the dope stays in the extrusion machine was 7 minutes. The temperature Td of the dope at the exit 11a of the extrusion machine 11 was measured with the thermometer 37, and it was −70° C. Further, the temperature T0 of the unmodified solution 15 was 30° C. The averaged cooling speed calculated on the basis of the formula (T0−TD)/Tc was 15° C./min. Note that other conditions of Experiments 12&13 than those in Table 5 were the same as Experiment 1.

TABLE 5

| | Sf | Sp | Tc | TD | |
|---|---|---|---|---|---|
| | (m³/min) | (g/min) | (min) | (° C.) | Sol. |
| Ex. 1 | 5 × 10⁻⁵ | 50 | 7 | −70 | B |
| Ex. 12 | 7 × 10⁻⁴ | 700 | 0.5 | −65 | C |
| Ex. 13 | 18 × 10⁻⁶ | 18 | 20 | −70 | B *1 |

*1: The productivity became low.

In Experiment 12, the feeding speed Sf was 7×10⁻⁴m³/min, the cooling period Tc in the extrusion machine 11 was short and 0.5, and the solubility became lower (the estimation was B). Further, in Experiment 13, the feeding speed Sf was 18×10⁻⁶m³/min, and therefore the solubility of the dope was good (the estimation was B). However, the production speed Sp was 18 g/min, and small, and the productivity was therefore bad.

### EXAMPLE 6

The cooler 12 was disposed in the downstream from the extrusion machine 11 used in Experiment 1. Note that the explanation of Experiment 14 was made in detail, and the same explanations in Experiments 15-17 are omitted. The results of the estimation are illustrated in Table 6.

In Experiment 14 the cooler 12 was the pipe of the double pipe type (or double pipe). The two pipes each have the inner diameter D3 of 30 mm and the length of 1000 mm. Further, into the outer pipe 12b was fed the cooling medium (Frorinart; trade name) at −70° C., and the cooling medium circulator 19 was controlled such that the inner pipe 12a of the cooler 12 had the temperature of −70° C. The rotation number was controlled such that the production speed Sp was 50 g/min. In Experiment 15, the same extrusion machine (or the another extrusion machine) as in Experiment 1 was used as instead of the double pipe. Into the jacket was fed the cooling medium (Frorinart; trade name) at −70° C., and the cylinder had the temperature of −70° C. In this examination, the temperature of the cylinder was regarded as the temperature T(° C.) of the cooler. Further, In Experiment 16, the cooling medium 18 was fed into the outer pipe 12b of the double pipe, and had the temperature at −60° C., which was higher than the temperature T2 (−70° C. ) at the exit of the cylinder (T2<T1). In Experiment 17, the cooler 40 was used (see FIG. 4). The inner diameter of the inner pipe 40a was 30 mm, and the length was 1000 mm. The aspiration was made by the vacuum pump 41. The pressure was measured by the pressure gauge 42, and the value of the measured pressure was 1 ×10⁻³ Pa. Table 6 shows the experimental conditions and the results of estimation.

TABLE 6

| | | D2 | Length | Temperature | |
|---|---|---|---|---|---|
| | Type of Cooler | (mm) | (mm) | T (° C.) | Sol. |
| Ex. 1 | None | — | — | — | B |
| Ex. 14 | Double Pipe | 30 | 1000 | −70 | A |
| Ex. 15 | Extrusion | 30 | 1000 | −70 | A *2 |
| | machine | | | | |
| Ex. 16 | Double Pipe | 30 | 1000 | −60 | A |
| Ex. 17 | Double Pipe | 30 | 1000 | | A |
| | 1.3 × 10⁻³ Pa | | | | |
| Ex. 18 | Static Mixer | — | — | — | N |

Note that the temperature of the second section of the jacket in the extrusion machine was −70° C.
*2: The same extrusion machine was used as in Experiment 1.

In Experiments 14-17, the cooling was made after the compression and the preparation of the dope, and the solubility of the dope was extremely excellent (Estimation was A). In Experiment 16, the temperature T of the cooler was higher than the temperature T at the exit of the cylinder, and the solubility was extremely excellent. In Experiment 17, the cooler 40 having vacuum insulation pipe was used, and the good dope was obtained (Estimation was A). This result teaches that it is preferable in the present invention in which the dope having high viscosity is produced, to use the cooler of the double pipe type in which the increase of the pressure can be reduced.

[Examination 7]

The size (or the volume V2 in the cooler 12) of the cooler of the double pipe type was varied. The cooler of the double pipe type used in Examination 14 had the inner diameter D2 of the inner pipe was 30 mm, the length was 1000 mm. The volume V2 in the cooler 12 was 7×10⁻⁴m³. The volume V1 in the extrusion machine 11 was 3.5×10⁻⁴m³ The ratio (V2/V1) was 2. Further, the ratio (D2/D) of the inner diameter D2(mm) of an inner pipe 12a to the inner diameter D (mm) of the extrusion machine 11 was 1.0. The cooling medium (Frorinart trade name) at −70° C. was fed into the outer pipe of the double pipe such that the temperature T of the cooler might be −70° C. The rotation number of the screw 32 was adjusted such that the production speed of the dope might be 50 g/min. Further, in Experiment 18, the inner diameter D2 of the inner pipe was 30 mm, the length was 800 mm. The ratio (V2/V1) was 1.6. Further, the ratio (D2/D) was 1.0. Further, in Experiment 19, the inner diameter D2 was 30 mm, the length was 3500 mm. The ratio (V2/V1) was 24.9, and the ratio (D2/D) of inner diameter was 1.0. In Experiment 20, the inner diameter D2 was 24 mm, the length was 1550 mm. The ratio (V2/V1) was 2, and the ratio (D2/D) of inner diameter was 0.8. Table 7 shows the experimental conditions and the results of estimations of Experiments 14, 18-20.

TABLE 7

| | Double Pipe Type | | | | | | |
|---|---|---|---|---|---|---|---|
| | D2 | Length | V2 | | | Sp | |
| | (mm) | (mm) | (m³) | V2/V1 | D2/D | (g/min) | Sol. |
| Ex. 14 | 30 | 1000 | 7.1 × 10⁻⁴ | 2 | 1.0 | 50 | A |
| Ex. 18 | 30 | 800 | 5.7 × 10⁻⁴ | 1.6 | 1.0 | 50 | B |
| Ex. 19 | 30 | 3500 | 35 × 10⁻³ | 24.9 | 1.0 | 50 | B |
| Ex. 20 | 24 | 1550 | 7.0 × 10⁻⁴ | 2 | 0.8 | 50 | B |

The volume V1 in the extrusion machine 11 was 3.5×10⁻⁴m³, the inner diameter of the cylinder was 30 mm.

According to Table 7, in Experiment 14, the length of the pipe of double pipe type was 1000 m. In this case the obtained dope was better than the dope in Example 19, in which the length of the pipe of double pipe type was 3500 m. In the present invention it is the most adequate to use the pipe of the double pipe type, whose length of is preferably 1000 m. Further, In Experiment 14, the inner diameter of the double pipe type was 30 mm, and the obtained dope was better than in Experiment 20 in which the inner diameter of double pipe type was 24 mm. Therefore, the preferable inner diameter of the double pipe type is 30 mm. Accordingly, the inner diameter D in the cylinder and the inner diameter D2 of the inner pipe satisfy the condition of 0.8<(D2/D)<10.

[Examination 8]

The heater 13 was attached in downstream from the cooler 12. In Experiment 21, the heating process was performed in the same condition as the Experiment 14 after the low temperature keeping process. The heater 13 was produced by Noritake Company Limited, the heating speed was 40° C./min. Further, in Experiment 22, the heating speed was 18° C./min, and other conditions were the same as Experiment 21. The results are illustrated in Table 8 with that of Experiment 1.

TABLE 8

| | Production Speed | Heating Speed | |
|---|---|---|---|
| | (g/min) | (° C./min) | Sol. |
| Ex. 1 | 50 | Without Heater | B |
| Ex. 21 | 50 | 40 | A |
| Ex. 22 | 50 | 18 | A |

According to Table 8, the solubility is better in Examinations 21&22 in which the heating was made (estimation A). Further, the solubility of the dope in Experiment 21 was higher than that in Experiment 22. Accordingly, the solubility increases when the heating speed becomes higher.

According to the above described results of Experiments 1-5, 7-22, and Experiment 6 as the comparison, the dope of the best quality can be obtained in the apparatus and method of producing the dope of the present invention, when the screw is compression type, and the cooler and the heater are provided in the downstream side from the extrusion machine. Thereby, in order to improve the solubility and to feed the unmodified solution 15 (or the dope) easily, at least one of the experimental conditions may be selected. As the experimental conditions, there are a compression rate and a relation of the length of each screw (at least one of the conditions; both of A≦B and C≦B, 1.1≦(B/A)4, and 1.1≦(B/C)≦4), a height of the flight in the third portion of the screw, a temperature condition of extrusion machine, the cooler and the heater, flight of the extrusion machine, an inner diameter of the cylinder, a ratio (L/D), a form of the cooler, a volume rate (V2/V1) of the extrusion machine and the cooler, a rate of the inner diameter D of the cylinder and the inner diameter D2 of the pipe in the heater, The temperature TD at the exit of the extrusion machine, a cooling speed in the extrusion machine, a cooling period in the cooler, a temperature T2 at the exit of the cylinder of the extrusion machine, a relation (T≦T2) of the temperature T2 at the exit of the cylinder of the extrusion machine and the temperature of the cooler, and the like.

[Preparation of Dope B]

Dope B was prepared from the following contents, and used in the Experiments and Comparisons when the specific explanations.

| | |
|---|---|
| (Polymer) | |
| Cellulose triacetate | 25 pts. wt. |
| (acetyl value was 2.83, viscometric average degree of | |
| polymerization was 320, moisture content was 0.4 wt. %, | |
| viscosity of 6% by mass of dichloromethane solution was | |
| 305 mPa · s.) | |
| (Solvent) | |
| Methyl acetate | 75 pts. wt. |
| Cyclopentanone | 10 pts. wt. |
| Acetone | 5 pts. wt. |
| Methanol | 5 pts. wt. |
| Ethanol | 5 pts. wt. |
| (Additives) | |
| Plasticizer A (dipentaerythritholhexaacetate) | 1 pts. wt. |
| Plasticizer B (Triphenyl phosphate; TPP) | 1 pts. wt. |
| Particles (silica having diameter of 20 nm) | 0.1 pts. wt. |
| UV-absorbing agent a | 0.1 pts. wt. |
| (2,4-bis-(n-octylthio)-6-(4-hydroxy-3,5-di-tert- | |
| butylanylino)-1,3,5-triazine) | |
| UV-absorbing agent b | 0.1 pts. wt. |
| (2-(2′-hydroxy-3′,5′-di-tert-butylphenyl)-5- | |
| chrolobenzotriazol) | |
| UV-absorbing agent c | 0.1 pts. wt. |
| (2-(2′-hydroxy-3′,5′-di-tert-amilphenyl)-5- | |
| chrolobenzotriazol) | |
| C₁₂H₂₅OCH₂CH₂O—P(═O)—(OK)₂ | 0.05 pts. wt. |

[Production of Film]

The Dope A produced in the above described conditions of Experiment 13 and the Dope B were prepared, and cast such that the Dope A form an intermittent layer and the dope B may form front and rear layers. Thus the film having three-layer structure was formed in the solution casting method. In the film production apparatus, the casting die of the feed block type illustrated in FIG. 7 was used. Further, the belt as the substrate was endlessly moved at the speed of 50 m/min. The casting was made such that the front and rear layers had the thickness of 3 μm, and the intermittent layer had the thickness of 74 μm. The casting film, when having the self-supporting property, was peeled as the film from the belt with support of the peeling roller 70. Thereafter, the film is dried at about 145° C. for 15 minutes with a tenter dryer, then cooled at about 60° C. for two minutes with the cooler, and wound by the winding device. Thus the film whose thickness was 80 μm.

The surface retardation value of the film was measured with Ellipsometer (Polarization analyzer AEP-100, produced by Shimadzu Corporation). In the measurement, the Ellipsometer radiated the light whose wavelength was 632.8 nm. The surface retardation (Re) was the multiple value of the thickness to the difference of refraction indexes between longitudinal and transversal directions, and obtained in the following formula:

Re=(nx−ny)×d

nx: refractive index in longitudinal direction

ny: refractive index in transversal direction

d: thickness of film

Note that the longitudinal direction corresponds to the feeding direction of the film in the film production process, and the transversal direction corresponds to the widthwise direction of the film. In this Example, the smaller surface retardation (Re) is preferable, and the thickness of the film was measured and the measured value was 2 nm. The optical properties were excellent.

On the film obtained in the manner above described was formed an anti-reflection layer in the following processes.

(Preparation of Coating Solution A for Antiglare Layer)

In order to prepare a coating solution A for an antiglare layer, a mixture (DPHA, produced by NIPPON KAYAKU CO., LTD.) was used, in which dipentaerythritol pentaacrylate and dipentaerythritol hexaacrylate were mixed. The mixture of 125 g and bis(4-metacryloil thiophenyl) sulfide (MPSMA, produced by SUMITOMO SEIKA CHEMICALS CO., LTD.) of 125 g were dissolved in a mixture solvent of 439 g that contained methylethylketone of 50 wt. % and cyclohexanone of 50 wt. %. Thus a first solution was obtained. Further, second solution was prepared. In the second solution, a photoinitiator for radical polymerization (IRGACURE 907, produced by Chiba Gaigy Japan Limited) of 5.0 g and photosensitizer (KAYACURE DETX, produced by NIPPON KAYAKU CO., LTD.) of 3.0 g were dissolved in methylethyl ketone of 49 g. The second solution was added to the first solution to obtain an added solution. The added solution was coating and thereafter cured with ultraviolet ray to obtain a coating layer, which had reflective index of 1.60.

Further, crosslinked polystyrene particles (name of product: SX-200H, produced by Soken Chemical & Engineering Co., Ltd.) of 10 g, whose average particle diameter was 2 μm, were added to the added solution, and this mixture was stirred to disperse the crosslinked polystyrene particles with a high speed stirrer for an hour. The stir speed thereof was 5000 rpm. Thereafter, the filtration of the dispersed solution was made with a polypropylene filter having pores whose diameter each was 30 μm. Then the coating solution A for antiglare layer was obtained.

(Preparation of Coating Solution B for Antiglare Layer)

A mixture solvent containing cyclohexanone of 104.1 g and methylethyl ketone 61.3 g was stirred with an air stirrer. Thereby to the mixture solvent were added a coating solution for hard coat that contains DeSolite Z-7401 (containing zirconium oxide, and produced by JSR corporation) of 217.0 g, Kayarad DPHA of 91 g, methyl ethyl ketone (MEK) of 28 g, cyclohexanone (ANON) of 24 g and Irgacure of 10 g. Thus an added solution was obtained. Then it was cast and thereafter cured with ultraviolet ray to obtain a coating, which had refractive index of 1.61. Further, crosslinked polystyrene particles (name of product: SX-200H, produced by Soken Chemical & Engineering Co., Ltd.) of 5 g, whose average particle diameter was 2 μm, were added to the added solution, and this mixture was stirred to disperse the crosslinked polystyrene particles with a high speed stirrer for an hour. The stir speed thereof was 5000 rpm. Thereafter, the filtration of the dispersed solution was made with a polypropylene filter having pores whose diameter each was 30 μm. Then the coating solution B for antiglare layer was obtained.

(Preparation of Coating Solution C for Antiglare Layer)

In order to prepare a coating solution C for an antiglare layer, Methylethyl ketone and cyclohexanone were mixed in ratio of 54 wt. % and 46 wt. % for using as the solvent. Further, a mixture (DPHA, produced by NIPPON KAYAKU CO., LTD.) was used, in which dipentaerythritol pentaacrylate and dipentaerythritol hexaacrylate were mixed. The solvent of 52 g was supplied with 91 g of the mixture, and 218 g of hard coat solution containing zirconium oxide (DeSolite Z-7401, produced by JSR corporation). Thus the mixture was dissolved to obtain a mixed solution. Then in the mixed solution was dissolved a photoinitiator for radical polymerization composition (IRGACURE 907, produced by Chiba Gaigy Japan Limited) of 10 g to obtain an added solution. The added solution was coated and thereafter cured with ultraviolet ray to obtain a coating, which had refractive index of 1.61.

Further, crosslinked polystyrene particles (name of product: SX-200H, produced by Soken Chemical & Engineering Co., Ltd.) of 20 g, whose average particle diameter was 2 μm, were added to a mixture solvent of 80 g, in which methylethylketone of 54 wt. % and cyclohexanone of 46 wt. % were mixed. This solution was stirred to disperse the crosslinked polystyrene particles with high speed stirrer of 5000 rpm for an hour, and added to the added solution to obtain the dispersed solution. Thereafter, the filtration of the dispersed solution was made with a polypropylene filter having pores whose diameter each was 30 μm. Then the coating solution C for antiglare layer was obtained.

(Preparation of Coating Solution D for Hard Coating)

In order to prepare a coating solution D for a hard coating, Methylethylketone of 62 g and cyclohexanone of 88 g were mixed for using as the solvent. Then, UV-ray curable hard coat composition (DeSolite Z-7526, 72 wt. %, produced by JSR corporation) of 250 g was dissolved to the solvent. This obtained solution was coated and cured in ultraviolet ray to form a coating layer, which had refractive index of 1.53. Further, the solution was filtrated with a polypropylene filter having pores whose diameter each was 30 μm. Then the coating solution D for hard coating layer was obtained.

(Preparation of Coating Solution E for Low Reflective Index Layer)

MEK-ST of 8 g (average diameter of particles was 10 nm-20 nm, SiO₂ sol dispersion of methylethylketone, whose solids content degree was 30 wt. %, produced by Nissan Chemical Industries Co., Ltd.) and methylethylketone of 100 g were added to heat closslinked polymer (TN-049, produced by JSR Corporation) of 20093 g containing fluoride that had refractive index of 1.42. This mixture was stirred and filtrated with a polypropylene filter having pores whose diameter was 1 μm. Thus the coating solution E for low refractive index layer was obtained.

A surface of the cellulose triacetate film of 80 μm thickness that was produced in the above explained method was coated with the coating solution D by using a bar coater, and thereafter dried at 120° C. Then an UV light was applied to the coating layer on the film with air-cooled type metal halide lamp of 160 W/cm (produced by Eyegraphics Co., Ltd.). The illuminance was thereby 400 mW/cm², and illumination density was 300 mJ/cm². Thus the coating was cured to form the hard coat layer of thickness of 2.5 μm on the film.

Further, the coating solution A was applied on the hard coat layer on the film with the bar coater. The coating solution A was dried and cured in the same conditions as in forming the hard coat layer (namely in application of UV light). Thus the antiglare layer A of 1.5 μm was formed. Furthermore, the antiglare layer A was coated with the coating solution E for the low refractive index layer. Then the cross-linking was made at 120° C. for ten minutes to form a low refractive index layer whose thickness was 0.096 μm. Thus the antireflection film A was obtained. Furthermore, the coating solution B was used instead of the coating solution A, and other conditions were the same. Thus the antireflection film B was obtained. Further, the coating solution C was used instead of the coating solution A, and other conditions were the same. Thus the anti-reflection film C was obtained.

(Estimation of Antireflection Film)

The following examinations were made for the estimation of the respective antireflection films A, B, C according to the following items. The results of the examination was shown in Table 9.

(1) Specular Reflectance and Color Tint

A spectrophotometer V-550 (produced by JASCO Corporation) was provided with an adapter ARV-474 to measure the specular reflectance at an exiting angle of −5° according to the incident light of wavelength from 380 nm to 780 nm at the incident angle of 5°. Then the average of the specular reflectance of the reflection whose wavelength was from 450 nm to 650 nm was calculated to evaluate properties of antireflection.

A reflection spectrum was obtained from a data of the observation. Then from the reflection spectrum were calculated L* number, a* number and b* number in a CIE 1976 L*a*b* space, which represent the color tint of the regular reflection to a light generated with an incident angle at 5° by a CIE standard light source D65. The color tint was estimated on the basis of the L* number, a* number and b* number.

(2) Integral Reflectance

Further, a spectrophotometer V-550 (produced by JASCO Corporation) was provided with an adapter ILV-471 to measure the integral reflectance according to the incident light of wavelength between 380 nm and 780 nm at the incident angle of 5°. Then the average of the integral reflectance of the reflection whose wavelength was between 450 nm and 650 nm was calculated to evaluate antireflection properties.

(3) Haze

A haze meter MODEL 1001 DP, (produced by Nippon Denshoku Industries Co., Ltd.) was used for measurement of haze of the antireflection film.

(4) Pencil Hardness

The evaluations of pencil hardness were made as described in JIS K 5400 and the data thereof was used as a criterion of scratch resistance. After the antireflection film was set in atmosphere with the temperature of 25° C. and the humidity of 60% RH for two hours, the surface of the antireflection film was scratched with a 3H test pencil determined in JIS S 6006. Thereby a force of 1 kg was applied to the test pencil. The evaluation of the pencil hardness was:

“A”, when no scratch remains on the surface in evaluation of n=5 (n was trial number of performances of scratching);

“B”, when one or two scratches remained on the surface in evaluation of n=5;

“N”, when more than three scratches remain on the surface in evaluation of n=5.

(5) Contact Angle

After the antireflection film was set in the atmosphere at 25° C. and the humidity of 60% RH for two hours, the contact angle to the water on the antireflection film was measured, and the data thereof was used as a criterion of antistaining, especially finger printing stain proofness.

(6) Coefficient of Dynamic Friction

After the antireflection film was set in the atmosphere with the temperature of 25° C. and the relative humidity of 60% for two hours, the coefficient of dynamic friction was measured with a machine for measuring the coefficient of dynamic friction, HEIDON-14, in which a stainless steel ball of 5 mmφ was used. Thereby, the speed was set to 60 cm/min, and a force of 100 gw was applied to the surface of the antireflection film.

(7) Antiglare Property

First and second stimations of the antiglare properties were made to the 27 sorts of the obtained antireflection films. An fluorescent lamp (8000 cd/m²) without louver emitted a light onto each antireflection film and the light reflects. An image of the fluorescent lamp formed by the reflection was observed. Thus the estimation of antiglare property was made as follows:

“E” (Excellent) when no outline of the illumination lamp was observed;

“G” (Good) when the outline was slightly recognized;

“P” (Pass) when the outline was not clear but recognized;

“R” (Reject) when the outline was almost clear.

TABLE 9

| | SR | IR | H | PH | | Color Tint | | | |
|---|---|---|---|---|---|---|---|---|---|
| Film | (%) | (%) | (%) | (3H) | CA | L*/a*/b | DF | AP | SC |
| A | 1.1 | 2.0 | 8 | A | 103° | 10/1.9/1.3 | 0.08 | E | E |
| B | 1.1 | 2.0 | 8 | A | 102° | 9/2.0/−4.0 | 0.09 | E | E |
| C | 1.1 | 2.0 | 12 | A | 102° | 9/1.7/0.2 | 0.08 | E | E |

SR: Specular Reflectance
IR: Integral Reflectance
H: Haze
PH: Pencil Hardness
CA: Contact Angle
DF: Coefficient of Dynamic Friction
AP: Antiglare Property
SC: Surface Condition of Film

In this examination the dope produced in the method of the present invention was used to form the film, and the film was uses as the film base of the antireflection film which was excellent in optical properties, especially in the antiglare property and the antireflection property. Further, the color tint was weak, and the result of the estimation of the items according to the film properties, such as pencil hardness, finger printing stain proofness, coefficient of dynamic friction were good.

Then the above described film having three-layer structure was used for forming a antireflective polarizing sheet having antiglare properties. The polarizing sheet is used in a liquid crystal display, such that the antiglare layer may be disposed at the outermost position. Thereby no image of the fluorescent lamp formed by the reflection was observed, and therefore the contrast of the film was excellent. The reflection image was not and the film has the excellent visibility. The finger printing stain proofness was excellent.

Various changes and modifications are possible in the present invention and may be understood to be within the present invention.

What is claimed is:

1. An apparatus for producing a dope by compressing raw materials with an extrusion machine, said extrusion machine comprising:
a cylinder in which said raw materials are supplied through an entrance;
a jacket provided on outer side of said cylinder, a cooling medium being supplied into said jacket; and
a screw having a screw shaft and a spiral flight, and rotatably disposed in said cylinder, a gap between said cylinder and said screw shaft being narrower in a side of an exit of said extrusion machine.

2. An apparatus as defined in claim 1, wherein said screw is a single shaft type or a double shaft type.

3. An apparatus for producing a dope by cooling raw materials, said apparatus having a first extrusion machine which includes in a cylinder a single shaft screw constructed of a screw shaft and a spiral flight, said screw shaft comprising;
a first screw shaft portion having a first diameter, said first portion being positioned in a side for supply of said dope into said cylinder;
a second screw shaft portion having a second diameter larger than said first diameter, said second portion being positioned in a side for extrusion of said dope from said cylinder;
a third screw shaft portion connecting said first and second portions, a space between said third screw shaft portion and said cylinder being narrower in a moving direction of said dope.

4. An apparatus as defined in claim 3, wherein said third screw shaft portion compresses said raw materials.

5. An apparatus as defined in claim 4, wherein a length A(mm) of said first screw shaft portion, a length B(mm) of said third screw shaft portion, and a length C(mm) of said second screw shaft portion satisfy a following condition:
A≦B, and C≦B.

6. An apparatus as defined in claim 4, wherein a length A(mm) of said first screw shaft portion, a length B(mm) of said third screw shaft portion, and a length C(mm) of said second screw shaft portion satisfy a following condition:
1.1≦(B/A)≦4, and 1.1≦(B/C)≦4.

7. An apparatus as defined in claim 4, wherein said raw materials or said dope is compressed at a compression rate of more than 1.0 and at most 5.

8. An apparatus as defined in claim 7, wherein a gap between said second screw shaft portion and said cylinder is in the range of 1.5 mm to 6 mm.

9. An apparatus as defined in claim 8, wherein a jacket is provided in a periphery of said cylinder of said first extrusion machine, and said jacket is partitioned into two sections.

10. An apparatus as defined in claim 4, wherein a length L(mm) of a leading portion of said first extrusion machine and an inner diameter D(mm) of said cylinder satisfy a following condition:
5<(L/D)<50.

11. An apparatus for producing a dope, comprising:
an extrusion machine for producing said dope by cooling raw materials of said dope with rotation of a screw; and
a cooler provided in downstream from said extrusion machine.

12. An apparatus as defined in claim 10, wherein a cooler is provided downstream from said first extrusion machine.

13. An apparatus as defined in claim 12, wherein a second extrusion machine is used as said cooler.

14. An apparatus as defined in claim 12, said cooler is a double pipe type, and a cooling medium flows through an outer path of said pipes.

15. An apparatus as defined in claim 14, wherein a circulator for circulating said cooling medium is connected to said outer path.

16. An apparatus as defined in claim 12, wherein said cooler is a double pipe type, and has a vacuum thermal-insulation structure.

17. An apparatus as defined in claim 14, wherein a first volume V1 of said raw materials or said dope in said first extrusion machine and a second volume V2 of said dope in said cooler preferably satisfy the condition;
0.5≦(V2/V1)≦100

18. An apparatus as defined in claim 14, wherein an inner diameter D(mm) of said cylinder of said first extrusion machine and a inner diameter D2(mm) of an inner pipe of said double pipe satisfy the condition;
0.8<(D2/D)<10

19. An apparatus as defined in claim 12, wherein a heater is disposed in downstream from said cooler.

20. A method of producing a dope by cooling raw materials containing polymer and solvent, comprising:
using an extrusion machine including a screw having a shape for compressing said raw materials or said dope.

21. A method as defined in claim 20, wherein said screw of said extrusion machine is a single shaft type or a double shaft type.

22. A method as defined in claim 21, wherein a temperature TD of said dope at an exit of said extrusion machine is at most −30° C.

23. A method as defined in claim 21, wherein said raw materials or said dope is cooled at a cooling speed in the range of 5° C./min to 200° C./min in said extrusion machine.

24. A method as defined in claim 21, wherein said dope prepared in said extrusion machine is cooled in 60 minutes.

25. A method as defined in claim 24, wherein the cooling of said dope is performed with use of a pipe of a double pipe type provided in a downstream from said extrusion machine.

26. A method as defined in claim 25, wherein a cooling medium flowing through said outer path of said pipe of double pipe type is at least one of methanol, hydrofluoro ethers, and brine.

27. A method as defined in claim 21,
wherein a jacket partitioned into two sections is provided on a periphery of said cylinder of said extrusion machine, and
wherein a temperature T1(° C.) at an entrance of said cylinder for supply of said dope and a temperature T2(° C.) at an exit of said cylinder for discharge of said dope satisfy a condition:
T2<T1

28. A method as defined in claim 27, wherein a temperature T(° C.) in said cooler and said temperature T2(° C.) of said exit of said cylinder satisfy a condition:
T≦0.95≦T2.

29. A method as defined in claim 23, wherein said dope is heated at a heating speed of at least 20° C./min after being cooled.

30. A method as defined in claim 20, wherein said polymer is cellulose acylate.
